(19) United States
(12) Patent Application Publication
(10) Pub. No.: US 2013/0319841 A1
(43) Pub. Date: Dec. 5, 2013

(54) TOUCH PANEL

(71) Applicant: SHIH HUA TECHNOLOGY LTD., Zhubei City (TW)

(72) Inventors: CHIH-HAN CHAO, Hsinchu (TW); PO-SHENG SHIH, Hsinchu (TW); JIA-SHYONG CHENG, Hsinchu (TW)

(73) Assignee: SHIH HUA TECHNOLOGY LTD., Zhubei City (TW)

(21) Appl. No.: 13/730,812

(22) Filed: Dec. 28, 2012

(30) Foreign Application Priority Data
May 29, 2012 (TW) 101119225

(51) Int. Cl. H03K 17/96

(52) U.S. Cl. CPC H03K 17/962; B82Y 15/00
USPC 200/600; 977/956

(57) ABSTRACT

A touch panel includes a first conductive layer, an insulating layer and a second conductive layer. The first conductive layer, the insulating layer, and the second conductive layer are stacked in that order. The first conductive layer includes a carbon nanotube layer. The carbon nanotube layer includes a large number of carbon nanotubes, and the carbon nanotubes are arranged substantially along a first direction. The second conductive layer includes a number of metal strips. The metal strips are spaced from each other. The metal strips are arranged substantially along a second direction, and the first direction and the second direction are intersected.

### CROSS-REFERENCE TO RELATED APPLICATIONS

This application claims all benefits accruing under 35 U.S.C. §119 from Taiwan Patent Application No. 101119225, filed on May 29, 2012, in the Taiwan Intellectual Property Office, the disclosure of which is incorporated herein by reference.

### BACKGROUND

### 1. Technical Field

The disclosure relates to touch panels and, particularly, to a carbon nanotube-based touch panel.

### 2. Description of Related Art

Various electronic apparatuses such as computers, mobile phones, household electrical appliances, toys and the like are equipped with optically transparent touch panels applied over display devices. The electronic apparatus is operated when contact is made with the touch panel corresponding to elements appearing on the display device. A demand thus exists for such touch panels to maximize visibility and reliability in operation.

From the property of light transmittance, touch panels can be transparent or opaque. Printed circuit boards (PCB) are used in opaque touch panels. However, using the PCB in small household electrical appliances, toys and keyboard equipped with touch panels will increase cost. In addition, a larger size PCB has a great thickness and weight.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of a touch panel in one embodiment.

FIG. 2 is a vertical view of the touch panel of FIG. 1 assembled.

FIG. 3 shows a Scanning Electron Microscope (SEM) image of a carbon nanotube layer of FIG. 1.

FIG. 4 is a transverse cross-sectional view of a touch panel in another embodiment.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

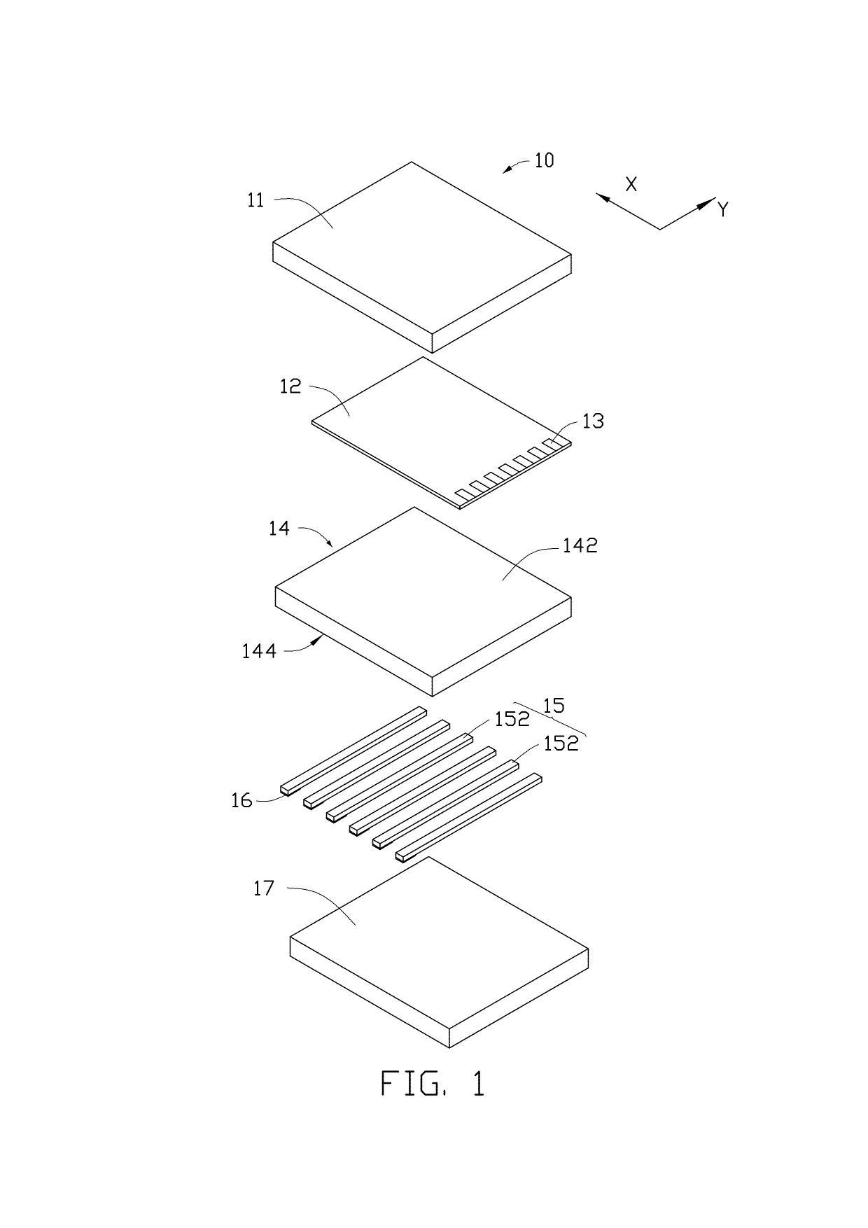

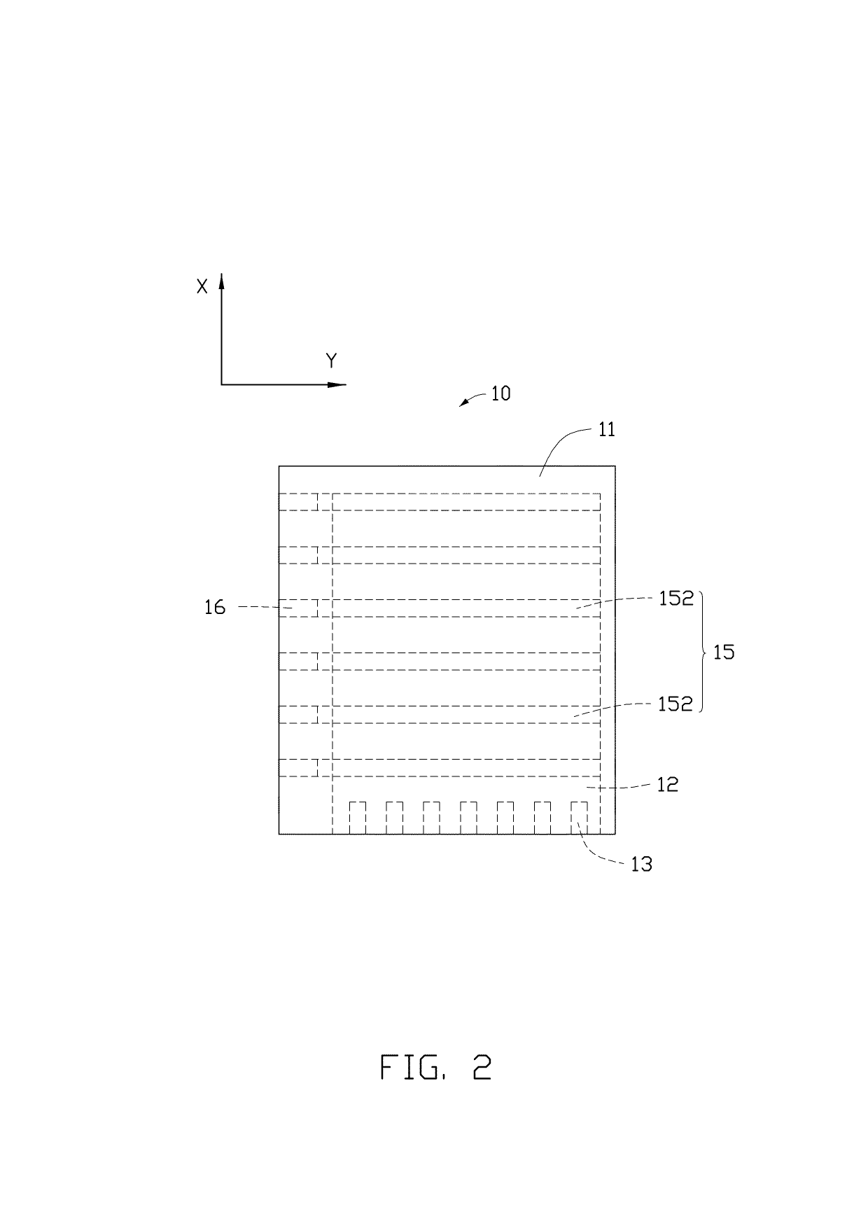

Referring to FIG. 1 and FIG. 2, one embodiment of a touch panel 10 includes a first conductive layer 12, a plurality of first electrodes 13, an insulating layer 14, a second conductive layer 15, and a plurality of second electrodes 16.

The first conductive layer 12, the insulating layer 14, and the second conductive layer 15 are stacked in that order. The plurality of first electrodes 13 are electrically connected to the first conductive layer 12. The plurality of first electrodes 13 are spaced from each other. The plurality of second electrodes 16 are electrically connected to the second conductive layer 15. The plurality of second electrodes 16 are spaced from each other.

The insulating layer 14 includes a first surface 142 and a second surface 144. The first surface 142 is opposite to the second surface 144. The first conductive layer 12 is located on the first surface 142 of the insulating layer 14. The second conductive layer 15 is located on the second surface 144 of the insulating layer 14.

In detail, the insulating layer 14 is a flexible film or a flexible plate made of polymer, resin, or any other flexible material. The insulating layer 14 has a dielectric property. The insulating layer 14 can be transparent or opaque. The insulating layer 14 is made of glass, diamond, quartz, plastic, or any other suitable material. The insulating layer 14 can be made of a flexible material. The flexible material can be polycarbonate (PC), polymethyl methacrylate acrylic (PMMA), polyethylene terephthalate (PET), polyethersulfone (PES), polyvinyl chloride (PVC), benzocyclobutenes (BCB), polyesters, acrylic resins, acrylonitrile butadiene styrene (ABS), polyamide (PA), or combination thereof. The thickness of the insulating layer 14 can range from about 0.1 millimeters to about 1 centimeter. In one embodiment, the insulating layer 14 is made of PET and has a thickness of about 0.4 millimeters.

The first conductive layer 12 can be or can include a carbon nanotube layer formed of a plurality of carbon nanotubes. The thickness of the carbon nanotube layer can range about 0.5 nanometers to about 200 micrometers. The thickness of the carbon nanotube layer can be selected according to need. In one embodiment, the thickness of the carbon nanotube layer ranges about 100 nanometers to about 200 nanometers.

Because the carbon nanotubes provide superior strength, flexibility, and uniform conductivity to the carbon nanotube film, the touch panel 10 using the carbon nanotube layer is durable, flexible, and highly conductive.

A large number of the carbon nanotubes of the carbon nanotube layer are arranged substantially along the same direction. The carbon nanotube layer can comprise at least one carbon nanotube film. The carbon nanotube layer has good light transparency.

The light transparency of a single carbon nanotube film can be greater than 85%. In one embodiment, the carbon nanotube layer can comprise at least two stacked carbon nanotube films or a plurality of carbon nanotube films contiguously located side by side, and carbon nanotubes of the carbon nanotube films are arranged to be substantially oriented along the same direction.

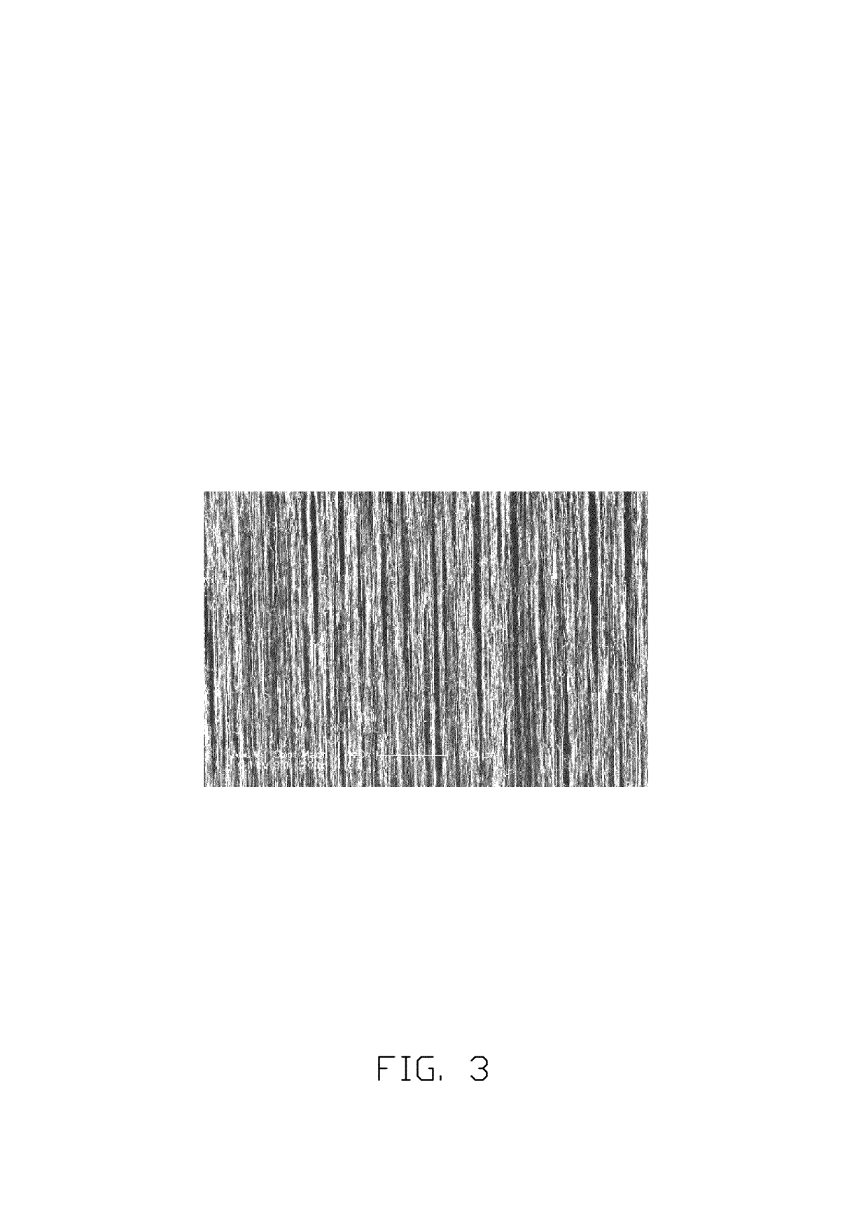

FIG. 3 shows a carbon nanotube film. The carbon nanotube film includes a plurality of carbon nanotubes that can be arranged substantially parallel to a surface of the carbon nanotube film. A large number of the carbon nanotubes of the carbon nanotube film can be oriented along a preferred orientation, meaning that a large number of the carbon nanotubes of the carbon nanotube film are arranged substantially along the same direction.

An end of one carbon nanotube of the large number of the carbon nanotubes is joined to another end of an adjacent one of the large number of the carbon nanotubes arranged substantially along the same direction, by van der Waals attractive force. A small number of the carbon nanotubes are randomly arranged in the carbon nanotube film, and has a small if not negligible effect on the larger number of the carbon nanotubes of the carbon nanotube film arranged substantially along the same direction. The carbon nanotube film is capable of forming a freestanding structure. The term “freestanding structure” can be defined as a structure that does not have to be supported by a substrate. For example, a freestanding structure can sustain its weight when hoisted by a portion thereof without any significant damage to its structural integrity. So, if the carbon nanotube film is placed between two separate supporters, a portion of the carbon nanotube film, not in contact with the two supporters, would be suspended between the two supporters and yet maintain film structural integrity. The freestanding structure of the carbon nanotube film is realized by the successive carbon nanotubes joined end to end by van der Waals attractive force.

Some variation can occur in the orientation of the carbon nanotubes of the carbon nanotube film as can be seen in FIG. 3. Microscopically, the carbon nanotubes oriented substantially along the same direction may not be perfectly aligned in a straight line, and some curve portions may exist. Some carbon nanotubes located substantially side by side and oriented along the same direction may be in contact with each other can not be excluded.

The carbon nanotubes of the carbon nanotube layer can be single-walled, double-walled, and/or multi-walled carbon nanotubes. The diameters of the single-walled carbon nanotubes can range from about 0.5 nanometers to about 50 nanometers. The diameters of the double-walled carbon nanotubes can range from about 1 nanometer to about 50 nanometers. The diameters of the multi-walled carbon nanotubes can range from about 1.5 nanometers to about 50 nanometers. The lengths of the carbon nanotubes can range from about 200 micrometers to about 900 micrometers.

The carbon nanotube layer can have different resistivity along the extending direction of carbon nanotubes and other directions. The ratio of the resistivity of the carbon nanotube layer along the extending direction of the carbon nanotubes and the resistivity of the carbon nanotube layer along other directions can be less than or equal to 1:2.

In one embodiment, the first conductive layer 12 is a carbon nanotube film. The light transparency of the first conductive layer 12 can be about 90%. The majority of the carbon nanotubes of the carbon nanotube film extend substantially along a first direction defined as an X axis. The resistivity of the carbon nanotube film along the X axis is less than the resistivity of the carbon nanotube film along a second direction defined as a Y axis. The X axis can cross the Y axis. In one embodiment, the X axis is substantially perpendicular to the Y axis. The first conductive layer 12 is a carbon nanotube layer with different conductivity along different directions. The resistivity of the first conductive layer 12 along the X axis is less than the resistivity of the first conductive layer 12 along the Y axis. In one embodiment, the ratio of the resistivity of the first conductive layer 12 along the Y axis and the resistivity of the first conductive layer 12 along the X axis is greater than 10:1. The first conductive layer 12 is divided into a plurality of conductive channels by the plurality of first electrodes 13.

The first conductive layer 12 can be located on the first surface 142 of the insulating layer 14 via adhesive, or can be directly attached to the first surface 142 because the carbon nanotube layer has a strong adhesive property.

The plurality of first electrodes 13 are located on the same side of the first conductive layer 12. The plurality of first electrodes 13 and the first conductive layer 12 form an electric path along the X axis. In one embodiment, the plurality of first electrodes 13 are located on opposite sides of the first conductive layer 12. In one embodiment, the plurality of first electrodes 13 can be located on the same side of the first conductive layer 12, the plurality of first electrodes 13 are arranged substantially along the X axis.

The plurality of first electrodes 13 can be made of electrically conductive materials, such as metal or carbon nanotubes. In one embodiment, the plurality of first electrodes 13 are made of silver.

The second conductive layer 15 can be an opaque conductive layer. The term “opaque” is that the light transmittance of the second conductive layer 15 under visible light is less than or equal to 50%. The touch panel 10 with the opaque second conductive layer 15 can be applied in opaque equipments, for example, a keyboard, remote controller, and tablet.

The material of the second conductive layer 15 can be metal. For example, the material of the second conductive layer 15 can be aluminum, silver, copper, iron, cobalt, nickel, or alloys thereof. The material of the second conductive layer 15 can be selected according to need.

The second conductive layer 15 includes a plurality of metal strips 152. The plurality of metal strips 152 are spaced from each other and form a pattern. The plurality of metal strips 152 can be bar shaped. The plurality of metal strips 152 are substantially parallel to each other. The plurality of metal strips 152 extend substantially along the Y axis. The plurality of metal strip 152 can be formed by forming a continuous metal conductive layer on the insulating layer 14 via evaporating or sputtering, and etching the continuous metal conductive layer. In one embodiment, the plurality of metal strips 443 can be formed on the second surface 144 of the insulating layer 14 via printing, spraying, or nano-imprinting. The method of forming the plurality of metal strips 443 is simple.

The thickness of each of the plurality of metal strips 152 can be selected according to need. The thickness of each of the plurality of metal strips 152 can be greater than 10 nanometers. For example, the thickness of each of the plurality of metal strips 152 can be about 50 nanometers, about 100 nanometers, about 250 nanometers, about 500 nanometers, about 1 micrometer, about 5 micrometers, about 10 micrometers, about 20 micrometers, or about 100 micrometers. In one embodiment, the thickness of each of the plurality of metal strips 152 can be greater than or equal to 50 nanometers, and less than or equal to 30 micrometers. In one embodiment, the second conductive layer 15 is made of silver, the thickness of the second conductive layer 15 ranges from about 4 micrometers to about 25 micrometers. In one embodiment, the thickness of the second conductive layer 15 is about 5 micrometers.

The plurality of second electrodes 16 are located on the same side of the second conductive layer 15. The plurality of second electrodes 16 are spaced from each other. The plurality of second electrodes 16 are arranged substantially along the X axis. The plurality of second electrodes 16 and the plurality of metal strips 152 are located with a one-to-one correspondence. Each of the plurality of second electrodes 16 is electrically connected to each of the plurality of metal strips 443. The material of the plurality of second electrodes 16 is the same as the material of the plurality of first electrodes 13. In one embodiment, the plurality of second electrodes 16 are located on opposite sides of the second conductive layer 15, and the plurality of second electrodes 16 located on the same side of the second conductive layer 15 are arranged substantially along the X axis. In one embodiment, the plurality of second electrodes 16 can be omitted, the plurality of metal strips 152 can be electrically connected to an external voltage source by conducting wires.

The touch panel 10 includes a first substrate 11 and a second substrate 17. The first substrate 11, the first conductive layer 12, the insulating layer 14, the second conductive layer 15, and the second substrate 17 are stacked in that order. The material of the first substrate 11 and the second substrate 17 are flexible films/plates made of polymer, resin, or any other flexible material. The material of the first substrate 11 and the second substrate 17 can be the same as the material and the thickness of the insulating layer 14. The thickness of the first substrate 11 and the second substrate 17 can be the same as the thickness of the insulating layer 14. In one embodiment, the material of the first substrate 11 and the second substrate is polymethyl methacrylate acrylic (PMMA), and the thickness of the first substrate 11 and the second substrate 17 is about 0.55 millimeters.

Because the first conductive layer 12 and the second conductive layer 15 are spaced by the insulating layer 14, the plurality of conductive paths of the first conductive layer 12 and the plurality of conductive strips of the second conductive layer 15 are intercrossed. A plurality of electric capacities can be formed on the intercrossed locations. The plurality of electric capacities can be detected by an external circuitry electrically connected by the first electrode 13 and the second electrode 16. If a contact is made by a tool such as a finger, pen, or the like, electric capacities of the intercrossed locations are changed. Changes of electric capacities are detected to calculate the position of the contact.

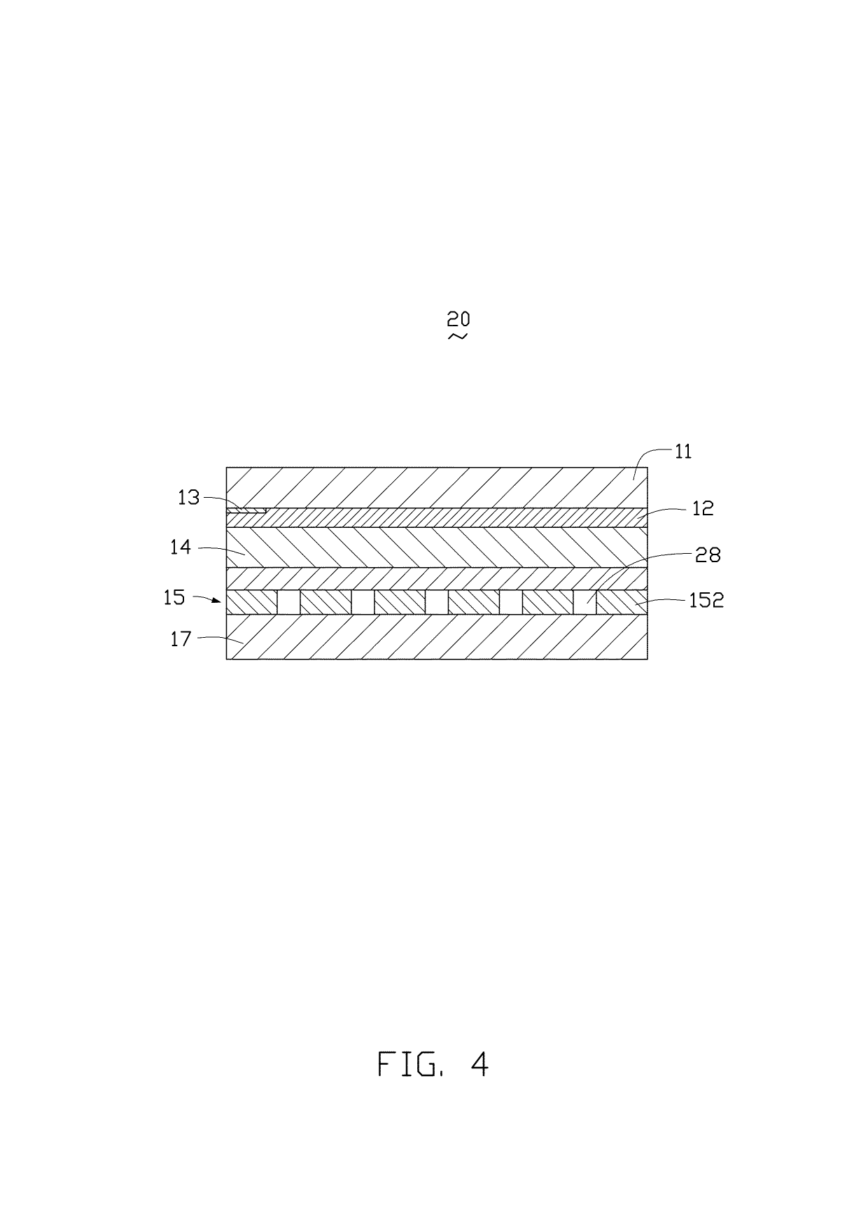

Referring to FIG. 4, another embodiment of a touch panel 20 includes a first conductive layer 12, a plurality of first electrodes 13, an insulating layer 14, a second conductive layer 15, and a plurality of second electrodes 16.

The touch panel 20 has a similar structure as the touch panel 10, except for an adhesive layer 28. The adhesive layer 28 is located between the second conductive layer 15 and the second surface 144 of the insulating layer 14. The second conductive layer 15 is located between the second substrate 17 and the adhesive layer 28. The adhesive layer 28 fixes the second conductive layer 15 on the second surface 144 of the insulating layer 14.

The material of the adhesive layer 28 can be optical adhesive, pressure-sensitive adhesive, polyvinyl butyral adhesive, and acrylic adhesive. The adhesive layer 28 can be an opaque layer. In one embodiment, the material of the adhesive layer 28 is optical adhesive.

The second conductive layer 15 can be formed on the second substrate 17 by evaporating, sputtering, spraying, or printing. The material of the second substrate 17 can be hard materials, such as glass or quartz. In one embodiment, the material of the second substrate 17 is glass, and the second conductive layer 15 is formed on second substrate 17 by evaporating aluminum source.

The other structure of the touch panel 20 can be the same or similar to the structure of the touch panel 10.

The touch panel has many advantages. First, the touch panel with the opaque second conductive layer can be applied in opaque equipments, such as a keyboard, remote controller, and tablet. Second, the size and the thickness of the carbon nanotube layer and the second conductive layer made of metal can be easily controlled, thus the cost will be reduced.

Third, the second conductive layer can be deposited via spraying or printing to form a pattern, thus the method of making the touch panel is simple. Lastly, the carbon nanotube film and the second conductive layer including the plurality of metal strips have good flexibility. If the first substrate and the second substrate are made of a flexible material, the touch panel can also have good flexibility.

It is to be understood that the described embodiments are intended to illustrate rather than limit the disclosure. Any elements described in accordance with any embodiments is understood that they can be used in addition or substituted in other embodiments. Embodiments can also be used together. Variations may be made to the embodiments without departing from the spirit of the disclosure. The disclosure illustrates but does not restrict the scope of the disclosure.

What is claimed is:

1. A touch panel comprising:
a first conductive layer comprising a carbon nanotube layer, wherein the carbon nanotube layer comprises a plurality of carbon nanotubes, and the plurality of carbon nanotubes extend substantially along a first direction;
an insulating layer; and
a second conductive layer comprising a plurality of metal strips, wherein the first conductive layer, the insulating layer, and the second conductive layer are stacked in that order, the plurality of metal strips are spaced from each other, the plurality of metal strips are arranged substantially along a second direction, and the first direction and the second direction are intersected.

2. The touch panel of claim 1, wherein the plurality of metal strips comprises a material selected from the group consisting of aluminum, silver, copper, iron, cobalt, and nickel.

3. The touch panel of claim 1, wherein a thickness of each of the plurality of metal strips is greater than 10 nanometers.

4. The touch panel of claim 1, wherein the carbon nanotube layer is at least one carbon nanotube film, a majority of the carbon nanotubes of the at least one carbon nanotube film are oriented along a preferred orientation, and one end of one of the large number of carbon nanotubes is joined to another end of an adjacent one of the large number of carbon nanotubes arranged substantially along the same direction, by van der Waals attractive force.

5. The touch panel of claim 1, wherein the carbon nanotube layer is a freestanding structure and located on the insulating layer directly.

6. The touch panel of claim 1, further comprising a plurality of first electrodes and a plurality of second electrodes, the plurality of first electrodes are spaced from each other and electrically connected to the first conductive layer, the plurality of second electrodes are spaced from each other and electrically connected to the second conductive layer.

7. The touch panel of claim 6, wherein the plurality of first electrodes are located on the same side of the first conductive layer, and the plurality of first electrodes are arranged substantially along the first direction.

8. The touch panel of claim 6, wherein the plurality of second electrodes are located on the same side of the second conductive layer, the plurality of second electrodes and the plurality of metal strips are located with a one-to-one correspondence, and each of the plurality of second electrodes is electrically connected to one of the plurality of metal strips.

9. The touch panel of claim 1, wherein the insulating layer comprises a first surface and a second surface, the first surface is opposite to the second surface, the first conductive layer is located on the first surface of the insulating layer, and the second conductive layer is located on the second surface of the insulating layer.

10. The touch panel of claim 1, wherein the insulating layer comprises a material selected from the group consisting of polycarbonate, polymethyl methacrylate acrylic, polyethylene terephthalate, polyethersulfone, polyvinyl chloride, benzocyclobutenes, polyesters, acrylic resins, acrylonitrile butadiene styrene, polyamide, and combination thereof.

11. The touch panel of claim 1, wherein the second conductive layer is formed via spraying, evaporating, sputtering, or printing.

12. The touch panel of claim 1, further comprising an adhesive layer located between the second conductive layer and the insulating layer.

13. The touch panel of claim 12, wherein the adhesive layer comprises a material selected from the group consisting of optical adhesive, pressure-sensitive adhesive, polyvinyl butyral adhesive, and acrylic adhesive.

14. A touch panel comprising:
a first substrate;
a first conductive layer located on the first substrate and comprising a carbon nanotube layer, wherein the carbon nanotube layer comprises a plurality of carbon nanotubes, and the plurality of carbon nanotubes extend substantially along a first direction;
a first adhesive layer;
an insulating layer comprising a first surface and a second surface opposite to the first surface, wherein the first surface of the insulating layer is stacked on the first conductive layer by the first adhesive layer; and
a second conductive layer located on the second surface of the insulating layer and comprising a plurality of metal strips, wherein the plurality of metal strips are spaced from each other and arranged substantially along a second direction, and the first direction and the second direction are intersected.

15. The touch panel of claim 14, further comprising a second adhesive layer located between the second conductive layer and the insulating layer.

16. The touch panel of claim 14, wherein the carbon nanotube layer is a freestanding structure and located on the first substrate directly.

17. The touch panel of claim 14, wherein the second conductive layer is formed via sputtering or printing.
